(19) United States
(12) Patent Application Publication
(10) Pub. No.: US 2026/0134909 A1
(43) Pub. Date: May 14, 2026

(54) SEMICONDUCTOR MEMORY APPARATUS AND INITIALIZATION METHOD THEREOF

(71) Applicant: Winbond Electronics Corp., Taichung City (TW)

(72) Inventor: Jun-Lin Yeh, Zhubei City (TW)

(73) Assignee: Winbond Electronics Corp., Taichung City (TW)

(21) Appl. No.: 19/051,145

(22) Filed: Feb. 11, 2025

(30) Foreign Application Priority Data
Nov. 14, 2024 (TW) 113143861

(51) Int. Cl. G11C 11/418; G11C 11/419

(52) U.S. Cl. CPC G11C 11/418; G11C 11/419

(57) ABSTRACT

Disclosed are a semiconductor memory apparatus and an initialization method thereof. The semiconductor memory apparatus includes a memory array, an address input buffer, a decoder, and a control circuit. The memory array has a plurality of memory blocks. Each of the memory blocks includes a plurality of storage units. The address input buffer is configured to receive address data. The decoder is configured to decode the address data. The control circuit is configured to receive a read write selection signal and a set signal, and initialize the memory blocks in sequence accordingly.

### CROSS-REFERENCE TO RELATED APPLICATION

This application claims the priority benefit of Taiwan application serial no. 113143861, filed on Nov. 14, 2024. The entirety of the above-mentioned patent application is hereby incorporated by reference herein and made a part of this specification.

### BACKGROUND

### Technical Field

The present invention relates to a method for memory operation, and particularly relates to a semiconductor memory apparatus and an initialization method thereof.

### Description of Related Art

Static random access memory (SRAM) is a type of volatile semiconductor memory apparatus. When using SRAM, it is required for a preset data pattern (for example, “FFh” or “00h”) to be written into the SRAM to conduct initialization. Conventionally, during the initialization period, write cycles are required to be performed for multiple times, which are likely to consume considerable time and exceed time limits, thereby resulting in incomplete initialization.

### SUMMARY

The present invention provides a semiconductor memory apparatus and an initialization method thereof, which may significantly reduce the time consumed for initialization.

A semiconductor memory apparatus of the present invention includes a memory array, an address input buffer, a decoder, and a control circuit. The memory array has a plurality of memory blocks. Each of the memory blocks includes a plurality of storage units. The address input buffer is configured to receive address data. The decoder is coupled to the memory array and the address input buffer, and is configured to decode the address data. The control circuit is coupled to the decoder and is configured to receive a read write selection signal and a set signal, and initialize the memory blocks in sequence accordingly.

The initialization method of the semiconductor memory apparatus of the present invention includes the following steps: receiving address data to decode the address data; receiving a read write selection signal and a set signal, and initializing the memory blocks in sequence accordingly.

Based on the above, the semiconductor memory apparatus and the initialization method thereof in the present invention may initialize the memory blocks in sequence through a set operation. As a result, the time consumed for initialization may be significantly reduced, thereby preventing exceeding time limits and enabling complete initialization.

To make the above-mentioned features and advantages of the present invention more comprehensible, exemplary embodiments are described in detail below with reference to the accompanying drawings.

### BRIEF DESCRIPTION OF THE DRAWINGS

FIG. 1 illustrates a block diagram of a semiconductor memory apparatus of the present invention.

FIG. 2 illustrates a waveform diagram of a set operation of the semiconductor memory apparatus of the present invention.

FIG. 3 illustrates a waveform diagram of the write operation and read operation of the semiconductor memory apparatus of the present invention.

FIG. 4 illustrates a flowchart of steps of an initialization method for the semiconductor memory apparatus of the present invention.

### DESCRIPTION OF THE EMBODIMENTS

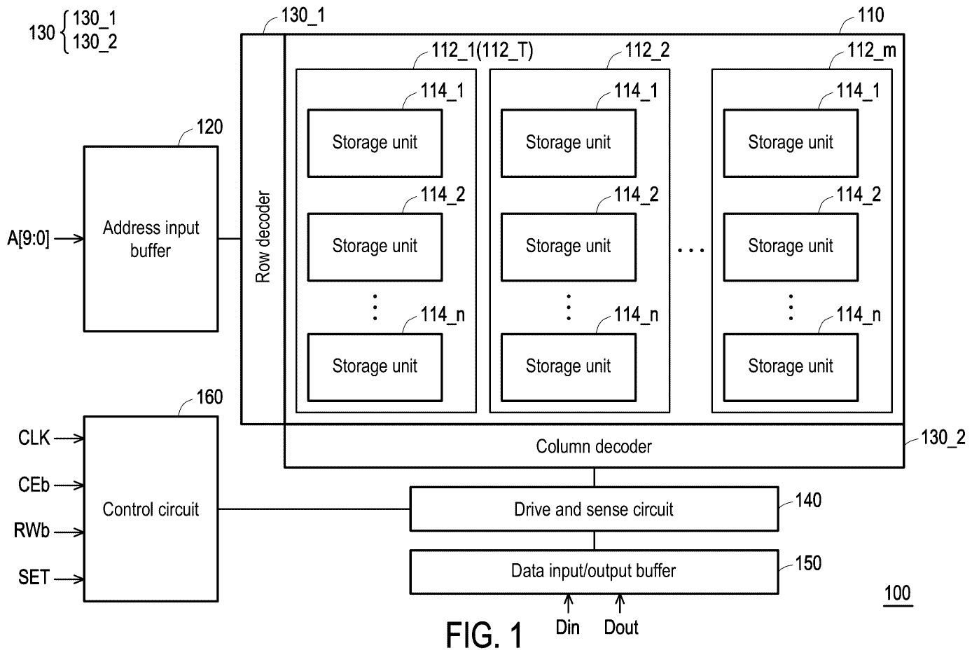

Please refer to FIG. 1, the semiconductor memory apparatus 100 includes a memory array 110, an address input buffer 120, a decoder 130, a drive and sense circuit 140, a data input/output buffer 150, and a control circuit 160. The memory array 110 may be, for example, a SRAM array, having m memory blocks 112_1 to 112_m. Each of the memory blocks 112_1 to 112_m includes n storage units 114_1 to 114_n. The size of each of the storage units 114_1 to 114_n may be, for example, one byte, which may be mapped by a corresponding memory address, but the present invention is not limited thereto. The size of each of the storage units 114_1 to 114_n may also be one word, one double-word, or any other arbitrary size. In view of the foregoing, each of the memory blocks 112_1 to 112_m may correspond to different ranges of memory addresses. Furthermore, m and n are positive integers greater than 2, m may be 16, n may be 64, for example, but the quantities of m and n are not intended to limit the present invention.

The address input buffer 120 may be configured to receive address data A[9:0]. The size of the address data A[9:0] may be, for example, 10 bits, and the 7th to the 10th bits located at the high-order address in the address data A[9:0] are referred to as high-order address bits A[9:6], while the 1st to the 6th bits located at the low-order address in the address data A[9:0] are referred to as low-order address bits A[5:0].

The decoder 130 is coupled to the memory array 110 and the address input buffer 120, and may be configured to decode the address data A[9:0], and select the memory block and storage unit to be operated based on the decoding result. Furthermore, the decoder 130 includes a row decoder 130_1 and a column decoder 130_2. The row decoder 130_1 may be configured to implement the selection of word lines in the memory array 110, and the column decoder 130_2 may be configured to implement the selection of bit lines in the memory array 110. In this way, the decoder 130 may select a target memory block 112_T to be operated from the memory blocks 112_1 to 112_m based on the 4 high-order address bits A[9:6] in the address data A[9:0], and the decoder 130 may select a storage unit to be operated from the storage units 114_1 to 114_n of the target memory block 112_T based on the 6 low-order address bits A[5:0] in the address data A[9:0]. It should be noted that although FIG. 1 shows the situation where the memory block 112_1 is selected as the target memory block 112_T, this situation is only an example, and the memory block serving as the target memory block 112_T will change as address data A[9:0] varies.

The drive and sense circuit 140 is coupled to the column decoder 130_2, and may be, for example, a combination of a write driver and a sense amplifier.

The data input/output buffer 150 is coupled to the drive and sense circuit 140, and may be configured to receive input data Din and provide output data Dout.

The control circuit 160 may be, for example, a central processing unit (CPU), or other programmable general-purpose or special-purpose microprocessor, digital signal processor (DSP), programmable controller, application-specific integrated circuits (ASIC), programmable logic device (PLD), or other similar devices or combinations of these devices. The control circuit 160 is coupled to the drive and sense circuit 140, and may be configured to receive a clock signal CLK, a chip enable signal CEb, a read write selection signal RWb, and a set signal SET, and initialize the memory blocks 112_1 to 112_m in sequence accordingly.

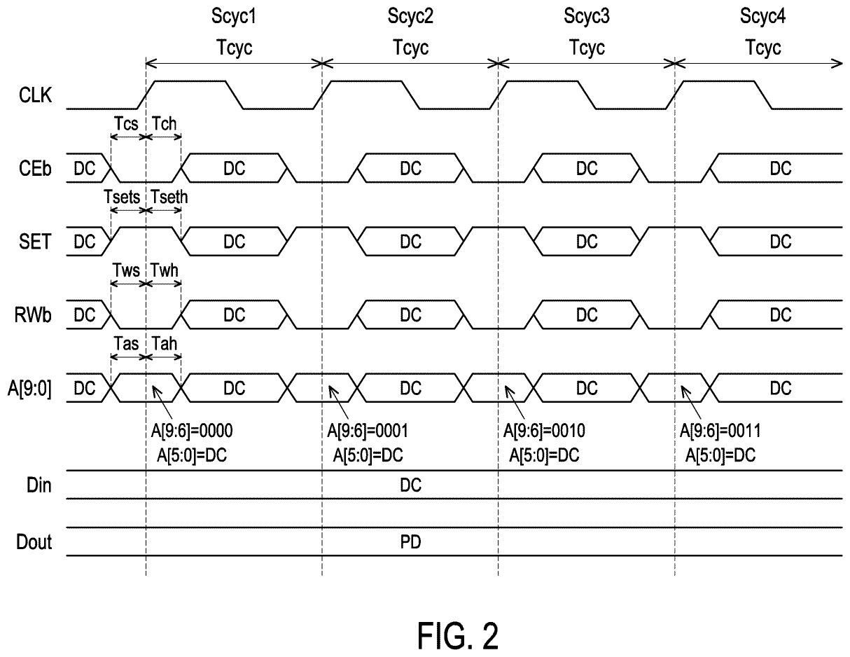

Specifically, FIG. 2 illustrates waveform diagrams of the clock signal CLK, the chip enable signal CEb, the read write selection signal RWb, the set signal SET, the address data A[9:0], the input data Din, and the output data Dout during the set cycles Scyc1 to Scyc4. As shown in FIG. 2, the cycle time Tcyc consumed by each of the set cycles Scyc1 to Scyc4 is equal to the clock cycle of the clock signal CLK. The control circuit 160 may respond to the rising edge of the clock signal CLK to capture the logic levels of the chip enable signal CEb, the read write selection signal RWb, and the set signal SET. In FIG. 2, the setup times Tcs, Tsets, Tws, Tas respectively represent how much earlier the chip enable signal CEb, the set signal SET, the read write selection signal RWb, and the address data A[9:0] need to be valid before the rising edge of the clock signal CLK. The hold times Tch, Tseth, Twh, Tah respectively represent how long the chip enable signal CEb, the set signal SET, the read write selection signal RWb, and the address data A[9:0] need to remain valid after the rising edge of the clock signal CLK. Those skilled in the art may appropriately adjust the setup times Tcs, Tsets, Tws, Tas and the hold times Tch, Tseth, Twh, Tah according to their actual needs and with reference to the teachings of this embodiment. Furthermore, in FIG. 2, DC represents a don't care state that does not affect the operation.

First, in the set cycle Scyc1, the high-order address bit A[9:6] of the address data A[9:0] is equal to “0000”, thereby the decoder 130 may select the memory block 112_1 as the target memory block 112_T. When the read write selection signal RWb is at a first logic level (low logic level), and the set signal SET is at a second logic level (high logic level), the control circuit 160 may conduct a set operation to write the preset data, which is pre-stored, into all storage units 114_1 to 114_n in the current target memory block 112_T (i.e., memory block 112_1) through the drive and sense circuit 140 within one cycle time Tcyc, thereby initializing the memory block 112_1.

Next, in the set cycle Scyc2, the high-order address bit A[9:6] of the address data A[9:0] is incremented to “0001”, thereby the decoder 130 may select the memory block 112_2 as the target memory block 112_T. When the read write selection signal RWb is at the first logic level, and the set signal SET is at the second logic level, the control circuit 160 may conduct a set operation to write the preset data, which is pre-stored, into all storage units 114_1 to 114_n in the current target memory block 112_T (i.e., memory block 112_2) through the drive and sense circuit 140 within one cycle time Tcyc, thereby initializing the memory block 112_2.

Similarly, in the set cycle Scyc3, the high-order address bit A[9:6] of the address data A[9:0] is incremented to “0010”, the control circuit 160 may write the preset data, which is pre-stored, into all storage units 114_1 to 114_n in the current target memory block 112_T (i.e., memory block 112_3) through the drive and sense circuit 140 within one cycle time Tcyc, thereby initializing the memory block 112_3. In the set cycle Scyc4, the high-order address bit A[9:6] of the address data A[9:0] is incremented to “0011”, the control circuit 160 may write the preset data, which is pre-stored, into all storage units 114_1 to 114_n in the current target memory block 112_T (i.e., memory block 112_4) through the drive and sense circuit 140 within one cycle time Tcyc, thereby initializing the memory block 112_4. By analogy, all memory blocks 112_1 to 112_m may be initialized sequentially.

In addition, when the chip enable signal CEb is at the second logic level, the semiconductor memory apparatus 100 will be in an idle state without conducting any operation. Therefore, in FIG. 2, the chip enable signal CEb captured by the control circuit 160 in response to the rising edge of the clock signal CLK needs to be at the first logic level to conduct the set operation.

Since the set operation in this embodiment writes the same preset data into all storage units 114_1 to 114_n in the current target memory block 112_T at once, there is no need to specify any individual storage unit among the storage units 114_1 to 114_n. Therefore, during the entire set operation period, the low-order address bits A[5:0] of the address data A[9:0] are all in a don't care state DC. Moreover, the input data Din is also in a don't care state DC, while the output data Dout may maintain the previously output data value PD.

When conducting the set operation, the control circuit 160 may also not use the pre-stored preset data, but instead write the input data Din input from the data input/output buffer 150 into all storage units 114_1 to 114_n in the current target memory block 112_T through the drive and sense circuit 140 within one cycle time Tcyc, thereby initializing the target memory block 112_T.

Through the aforementioned set operation, the control circuit 160 may simultaneously write data for initialization into all storage units 114_1 to 114_n in the target memory block 112_T within one cycle time Tcyc. In other words, the initialization of a memory block (64 bytes) corresponding to a large range of memory addresses may be completed within one cycle time Tcyc. As a result, the time consumed for initialization may be significantly reduced to prevent exceeding time limits, thereby enabling complete initialization.

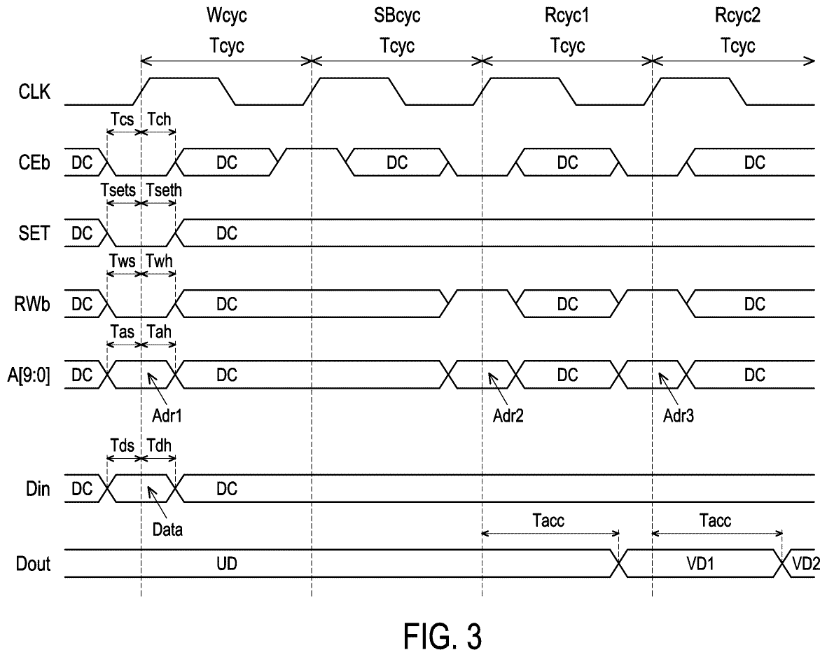

FIG. 3 illustrates waveform diagrams of the clock signal CLK, the chip enable signal CEb, the read write selection signal RWb, the set signal SET, the address data A[9:0], the input data Din, and the output data Dout during the write cycle Wcyc, the standby cycle SBcyc, and the read cycles Rcyc1 and Rcyc2. In FIG. 3, components with the same reference numerals as in FIG. 2 represent the same or similar parts. The setup time Tds indicates how much earlier the input data Din needs to be valid before the rising edge of the clock signal CLK, while the hold time Tdh indicates how long the input data Din needs to remain valid after the rising edge of the clock signal CLK.

First, in the write cycle Wcyc, the address data A[9:0] is the address value Adr1, thus the decoder 130 may select the target memory block 112_T to be operated on from the memory blocks 112_1 to 112_m accordingly, and select the corresponding storage unit to be operated on from the storage units 114_1 to 114_n of the target memory block 112_T. When the read write selection signal RWb and the set signal SET are at the first logic level, the control circuit 160 may conduct a write operation to write the input data Din into the corresponding storage unit in the target memory block 112_T through the drive and sense circuit 140.

Subsequently, in the standby cycle SBcyc, when the chip enable signal CEb is at the second logic level, the semiconductor memory apparatus 100 will be in an idle state without conducting any operation. Therefore, the set signal SET, the read write selection signal RWb, and the address data A[9:0] are all in a don't care state DC. Before the read cycle Rcyc1, the output data Dout is temporarily an unknown data value UD.

Next, in the read cycle Rcyc1, the address data A[9:0] is the address value Adr2, thus the decoder 130 may select the target memory block 112_T to be operated on from the memory blocks 112_1 to 112_m accordingly, and select the corresponding storage unit to be operated on from the storage units 114_1 to 114_n of the target memory block 112_T. When the read write selection signal RWb is at the second logic level, the control circuit 160 may conduct a read operation to read the data (data value VD1) stored in the corresponding storage unit in the target memory block 112_T through the drive and sense circuit 140, and output the read data as the output data Dout through the data input/output buffer 150 after the access time Tacc has elapsed.

In the read cycle Rcyc2, the address data A[9:0] is the address value Adr3, thus the decoder 130 may select the target memory block 112_T to be operated on from the memory blocks 112_1 to 112_m accordingly, and select the corresponding storage unit to be operated on from the storage units 114_1 to 114_n of the target memory block 112_T. When the read write selection signal RWb is at the second logic level, the control circuit 160 may conduct a read operation to read the data (data value VD2) stored in the corresponding storage unit in the target memory block 112_T through the drive and sense circuit 140, and output the read data as the output data Dout through the data input/output buffer 150 after the access time Tacc has elapsed.

It should be noted that during this period, the clock signal CLK, the chip enable signal CEb, the read write selection signal RWb, the set signal SET, the address data A[9:0], and the input data Din may be provided by a memory controller, for example. The memory controller may be, for example, a state machine, a central processing unit, or other programmable general-purpose or special-purpose microprocessors, digital signal processors, programmable controllers, application-specific integrated circuits, programmable logic devices, or other similar devices or combinations thereof, a device independent of the semiconductor memory apparatus 100, or may be located within the semiconductor memory apparatus 100. Furthermore, although in the above-mentioned embodiment, the operation is conducted with the first logic level being the low logic level and the second logic level being the high logic level, the present invention is not limited to this. In other embodiments, the operation may also be conducted with the first logic level being the high logic level and the second logic level being the low logic level.

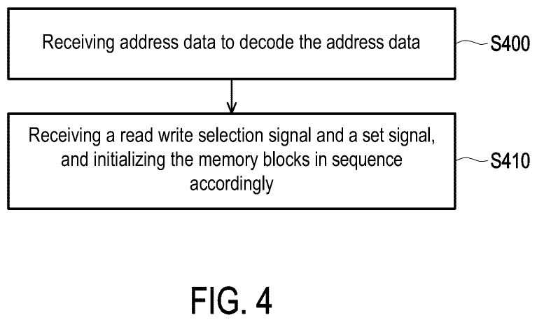

Please refer to FIG. 4, the initialization method for the semiconductor memory apparatus in this embodiment includes the following steps: receiving address data to decode the address data (step S400); receiving a read write selection signal and a set signal, and initializing the memory blocks in sequence accordingly (step S410). The implementation details of the above-mentioned steps S400 and S410 may refer to the embodiments of FIG. 1 to FIG. 3, and will not be repeated here.

In summary, the semiconductor memory apparatus and the initialization method thereof in the present invention may sequentially initialize memory blocks through set operations to simultaneously write data for initialization to all storage units corresponding to a wide range of memory addresses. As a result, the time consumed for initialization may be significantly reduced to prevent exceeding time limits, thereby enabling complete initialization.

What is claimed is:

1. A semiconductor memory apparatus, comprising:
a memory array, having a plurality of memory blocks, each of the memory blocks comprising a plurality of storage units;
an address input buffer, configured to receive address data;
a decoder, coupled to the memory array and the address input buffer, and configured to decode the address data; and
a control circuit, coupled to the decoder, and configured to receive a read write selection signal and a set signal, and to initialize the memory blocks in sequence accordingly.

2. The semiconductor memory apparatus as claimed in claim 1, wherein the decoder selects a target memory block from the memory blocks based on a plurality of high-order address bits in the address data.

3. The semiconductor memory apparatus as claimed in claim 2, further comprising:
a drive and sense circuit, coupled to the decoder and the control circuit.

4. The semiconductor memory apparatus as claimed in claim 3, wherein when the read write selection signal is at a first logic level, and the set signal is at a second logic level, the control circuit conducts a set operation to write preset data into all the storage units in the target memory block through the drive and sense circuit within one cycle time.

5. The semiconductor memory apparatus as claimed in claim 3, further comprising:
a data input/output buffer, coupled to the drive and sense circuit, and configured to receive input data,
wherein when the read write selection signal and the set signal are at a first logic level, the control circuit conducts a write operation to write the input data into the corresponding storage unit in the target memory block through the drive and sense circuit.

6. The semiconductor memory apparatus as claimed in claim 5, wherein when the read write selection signal is at the first logic level, and the set signal is at a second logic level, the control circuit conducts a set operation to write the input data into all the storage units in the target memory block through the drive and sense circuit within one cycle time.

7. The semiconductor memory apparatus as claimed in claim 5, wherein when the read write selection signal is at a second logic level, the control circuit conducts a read operation to read data stored in the corresponding storage unit in the target memory block through the drive and sense circuit, and outputs the read data as output data through the data input/output buffer.

8. The semiconductor memory apparatus as claimed in claim 1, wherein the control circuit receives a clock signal and a chip enable signal, and responds to the clock signal to capture logic levels of the read write selection signal, the set signal and the chip enable signal.

9. The semiconductor memory apparatus as claimed in claim 8, wherein when the chip enable signal is at a second logic level, the semiconductor memory apparatus is in an idle state.

10. The semiconductor memory apparatus as claimed in claim 1, wherein the memory array is a static random access memory array.

11. A method for initializing a semiconductor memory apparatus, wherein the semiconductor memory apparatus comprises a memory array having a plurality of memory blocks, each of the memory blocks comprising a plurality of storage units, the initialization method comprising the following steps:
receiving address data to decode the address data; and
receiving a read write selection signal and a set signal, and initializing the memory blocks in sequence accordingly.

12. The initialization method as claimed in claim 11, wherein the step of decoding the address data comprises:
selecting a target memory block from the memory blocks based on a plurality of high-order address bits in the address data.

13. The initialization method as claimed in claim 12, wherein the step of initializing the memory blocks in sequence accordingly comprises:
when the read write selection signal is at a first logic level, and the set signal is at a second logic level, conducting a set operation to write preset data into all the storage units in the target memory block within one cycle time.

14. The initialization method as claimed in claim 12, further comprising:
receiving input data; and
when the read write selection signal and the set signal are at a first logic level, conducting a write operation to write the input data into the corresponding storage unit in the target memory block.

15. The initialization method as claimed in claim 14, wherein the step of initializing the memory blocks in sequence accordingly comprises:
when the read write selection signal is at the first logic level, and the set signal is at a second logic level, conducting a set operation to write the input data into all the storage units in the target memory block within one cycle time.

16. The initialization method as claimed in claim 14, further comprising:
when the read write selection signal is at a second logic level, conducting a read operation to read data stored in the corresponding storage unit in the target memory block, and outputting the read data as output data.

17. The initialization method as claimed in claim 11, further comprising:
receiving a clock signal and a chip enable signal, and responds to the clock signal to capture logic levels of the read write selection signal, the set signal and the chip enable signal.

18. The initialization method as claimed in claim 17, wherein when the chip enable signal is at a second logic level, the semiconductor memory apparatus is in an idle state.

19. The initialization method as claimed in claim 11, wherein the memory array is a static random access memory array.
